(19) United States
(12) Patent Application Publication
(10) Pub. No.: US 2015/0206803 A1
(43) Pub. Date: Jul. 23, 2015

(54) METHOD OF FORMING INTER-LEVEL DIELECTRIC LAYER

(71) Applicant: UNITED MICROELECTRONICS CORP., Hsin-Chu City (TW)

(72) Inventors: Wei-Hsin Liu, Changhua County (TW); Tzu-Chin Wu, Chiayi County (TW); Jei-Ming Chen, Tainan City (TW); Yu-Ren Wang, Tainan City (TW); Chun-Yuan Wu, Yun-Lin County (TW); Chin-Fu Lin, Tainan City (TW)

(73) Assignee: UNITED MICROELECTRONICS CORP., Hsin-Chu City (TW)

(21) Appl. No.: 14/158,857

(22) Filed: Jan. 19, 2014

(51) Int. Cl. H01L 21/8234; H01L 21/311; H01L 21/02; H01L 21/3105

(52) U.S. Cl. CPC H01L 21/823462; H01L 21/31053; H01L 21/31116; H01L 21/02274; H01L 21/02271

(57) ABSTRACT

A method of forming an inter-level dielectric layer including the following step is provided. Two gate structures are formed on a substrate. A first oxide layer is formed to conformally cover the two gate structures and the substrate. The first oxide layer is etched ex-situ by a high density plasma (HDP) etching process. A second oxide layer is formed in-situ on the first oxide layer and fills a gap between the two gate structures by a high density plasma (HDP) depositing process.

### BACKGROUND OF THE INVENTION

1. Field of the Invention

The present invention relates generally to a method of forming a dielectric layer, and more specifically to a method of forming an inter-level dielectric layer.

2. Description of the Prior Art

Poly-silicon is conventionally used as a gate electrode in semiconductor devices such as metal-oxide-semiconductors (MOS). Besides, with the trend towards scaling down the size of semiconductor devices, conventional poly-silicon gates face problems such as lower performances due to boron penetration and unavoidable depletion effect. This increases the equivalent thickness of the gate dielectric layer, reduces the gate capacitance, and worsens the driving force of the devices. Therefore, work function metals that are suitable to be used as high-K gate dielectric layers maybe employed to replace the conventional poly-silicon gate to be the control electrode.

Not only for forming a semiconductor device including poly-silicon gates but also for forming a semiconductor device including metal gates, an interdielectric layer must be formed to cover theses gates for structures such as metal interconnect structures formed thereon and for electrically connecting these gates outwards. As the size of the semiconductor device shrinks, gaps between these gates become smaller, and thus causing the interdielectric layer to be harder to fill into these gaps, thereby voids are generated between these gates. These voids would decrease the electrical and mechanical performance of devices. For instance, as the interdielectric layer is formed and patterned to expose the poly-silicon gates, the voids are exposed; and then, the voids are filled by metal as for replacing the poly-silicon gates with metal gates; as a result, the metal filled into the voids will cause a short circuit. Besides, as the interdielectric layer is patterned by methods such as polishing processes, the hardness of the interdielectric layer is extremely important to prevent the interdielectric layer from scratching.

### SUMMARY OF THE INVENTION

The present invention provides a method of forming an inter-level dielectric layer, which forms an inter-level dielectric layer through sequentially performing a sub-atmospheric chemical vapor deposition process, a high density plasma etching process and a high density plasma chemical vapor depositing process, to improve gap filling and abrasion resistance and simplify processes.

The present invention provides a method of forming an inter-level dielectric layer including the following step. Two gate structures are formed on a substrate. A first oxide layer is formed to conformally cover the two gate structures and the substrate. The first oxide layer is etched ex-situ by a high density plasma (HDP) etching process. A second oxide layer is formed in-situ on the first oxide layer and filling a gap between the two gate structures by a high density plasma (HDP) depositing process.

According to the above, the present invention provides a method of forming an inter-level dielectric layer, which forms a first oxide layer to conformally cover the two gate structures and the substrate, ex-situ etching the first oxide layer by a high density plasma (HDP) etching process and then in-situ forming a second oxide layer on the first oxide layer and filling a gap between the two gate structures by a high density plasma (HDP) depositing process. Therefore, the gap filling can be improved since the first oxide layer is formed conformally and then etched to remove undesired parts. The abrasion resistance for the second oxide layer can be improved since the second oxide layer is formed by a high density plasma (HDP) depositing process, wherein an oxide layer formed by a high density plasma (HDP) depositing process has the hardness higher than an oxide layer formed by other processes such as a sub-atmospheric chemical vapor deposition process (SACVD). Besides, as the first oxide layer is etched and the second oxide layer is formed in-situ, processes can be simplified and pollution can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 schematically depict cross-sectional views of a method of forming an inter-level dielectric layer according to an embodiment of the present invention.

### DETAILED DESCRIPTION

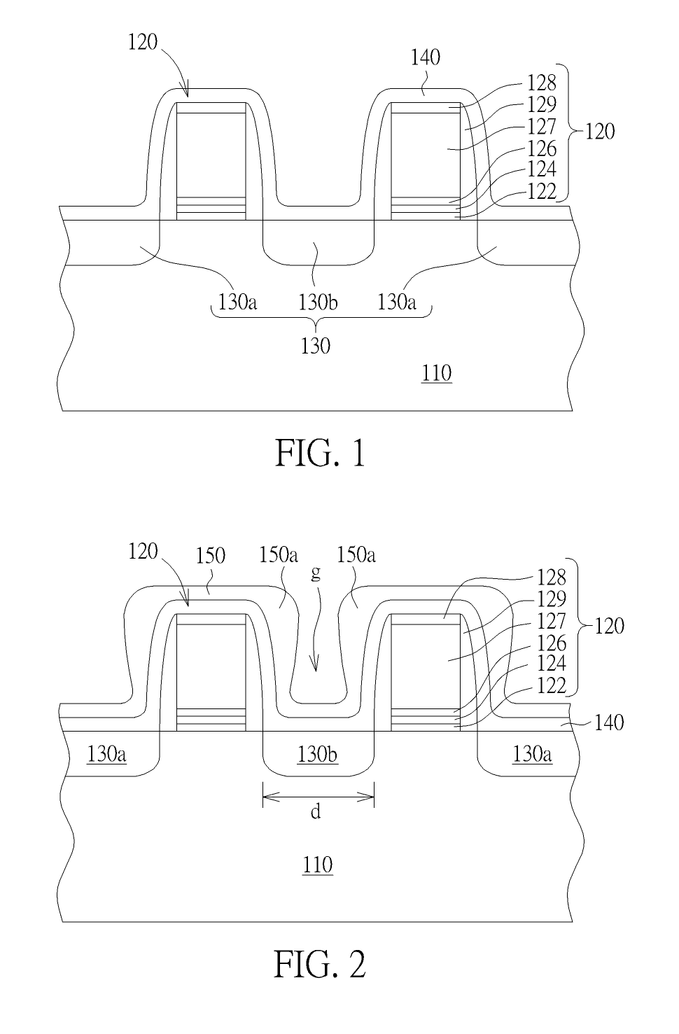

FIGS. 1-7 schematically depict cross-sectional views of a method of forming an inter-level dielectric layer according to an embodiment of the present invention.

As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. Two gate structures 120 are formed on the substrate 110. Each of the two gate structures 120 may include a buffer layer 122, a dielectric layer 124, a barrier layer 126, a gate 127 and a cap layer 128 from bottom to top, but it is not limited thereto. More precisely, a buffer layer (not shown), a dielectric layer (not shown), a barrier layer (not shown), a gate layer (not shown) and a cap layer (not shown) are sequentially and entirely formed on the substrate 110 and then are patterned to form the two gate structures 120 simultaneously, but it is not limited thereto.

The buffer layer 122 maybe an oxide layer formed by a thermal oxide processor a chemical oxide processor others. The buffer layer 122 is located between the gate dielectric layer 124 and the substrate 110 to buffer the gate dielectric layer 124 and the substrate 110. A gate-last for high-k first process is applied in this embodiment, so that the gate dielectric layer 124 is a gate dielectric layer having a high dielectric constant, which may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but it is not limited thereto. In another embodiment, as a gate-last for high-k last process is applied, the gate dielectric layer 124 will be removed in later processes and then a gate dielectric layer having a high dielectric constant is formed. Therefore, the material of the gate dielectric layer 124 maybe just a sacrificial material suitable for being removed in later processes. The barrier layer 126 is located on the gate dielectric layer 124 to prevent above disposed metals from diffusing downwards to the gate dielectric layer 124 and from polluting the gate dielectric layer 124. The barrier layer 126 maybe a single layer structure or a multilayer structure composed of tantalum nitride (TaN) or titanium nitride (TiN) or others. In this embodiment, the gate 127 may be made of polysilicon, but it is not limited thereto. The cap layer 128 may be a single layer or a multilayer composed of a nitride layer or an oxide layer or others used for being a patterned hard mask, but it is not limited thereto.

Spacers 129 of the gate structure 120 are formed on the substrate 110 beside the buffer layers 122, the dielectric layers 124, the barrier layers 126, the gates 128 and the cap layers 129. The method of forming the spacer 129 may include the following step. A spacer material (not shown) is conformally formed on the substrate 110 and the two gate structures 120, and then the spacer material is patterned to form the spacers 129. In this embodiment, the spacer 129 is a single spacer; but in another embodiment, the spacer 129 may be a multilayer spacer such as a dual spacer, depending upon the needs. The spacer 129 may be composed of silicon nitride or silicon oxide or others. Then, an ion implantation process is performed to automatically align and form source/drain regions 130 in the substrate 110 beside the two gate structures 120. In this embodiment, the source/drain regions 130 include two drain regions 130a and a common source 130b; that is, the two drain regions 130a are respectively beside the two gate structures 120 and the common source 130b is between the two gate structures 120, but it is not limited thereto. In another embodiment, the two gate structures 120 may have their source/drain regions individually. The source/drain regions 130 may be doped with pentavalent ions such as phosphorous ions for forming an N-type semiconductor structure; or, may be doped with trivalent ions such as boron ions for forming a P-type semiconductor structure.

Moreover, before/after the spacers 129 or the source/drain regions 130 are formed, lightly doped source/drain regions or epitaxial layers may be optionally formed beside the two gate structures. For example, before the spacer 129 is formed, spacers (not shown) may be formed on the substrate 110 beside the two gate structures 120, and then an ion implantation process maybe performed to self-align and form the lightly doped source/drain regions (not shown) in the substrate 110 beside the spacers. Thereafter, epitaxial spacers may be formed beside the spacers, and then the epitaxial layers (not shown) are self-aligned and formed in the substrate 110 beside the epitaxial spacers. However, the order of forming the lightly doped source/drain regions, the epitaxial layers and the source/drain regions 130 is not restricted thereto, depending upon the needs.

Thereafter, a salicide process may be selectively performed to form a metal silicide (not shown) on the source/drain regions 130. A contact etch stop layer (CESL) 140 may be selectively formed to conformally cover the substrate 110 and the gate structures 120. The contact etch stop layer 140 may be a doped nitride layer or a stress layer, but it is not limited thereto.

As shown in FIG. 2, a first oxide layer 150 is formed to conformally cover the two gate structures 120 and the substrate 110. In this embodiment, the first oxide layer 150 is formed by a sub-atmospheric chemical vapor deposition (SACVD) process, so that the first oxide layer 150 can conformally cover the two gate structures 120 and the substrate 110, especially for conformally covering the sidewalls of the gate structures 120 between the two gate structures 120, without having voids generating. Furthermore, as particles generating from previous processing steps remain, the first oxide layer 150 formed by a sub-atmospheric chemical vapor deposition (SACVD) process can still conformally cover the two gate structures 120 without having voids generating, thereby defects caused by these particles are avoided.

Preferably, the thickness of the first oxide layer 150 is in a range of 200˜300 angstroms while the spacing d of the two gate structures 120 is in a range of 400˜500 angstroms, thereby gap g is large enough for materials such as SACVD oxide to fill into through later processes of the present invention. However, as the first oxide layer 150 is formed, the first oxide layer 150 has overhang parts 150a, which would lead to the difficulty of filling materials such as oxide into the gap g between the gate structures 120.

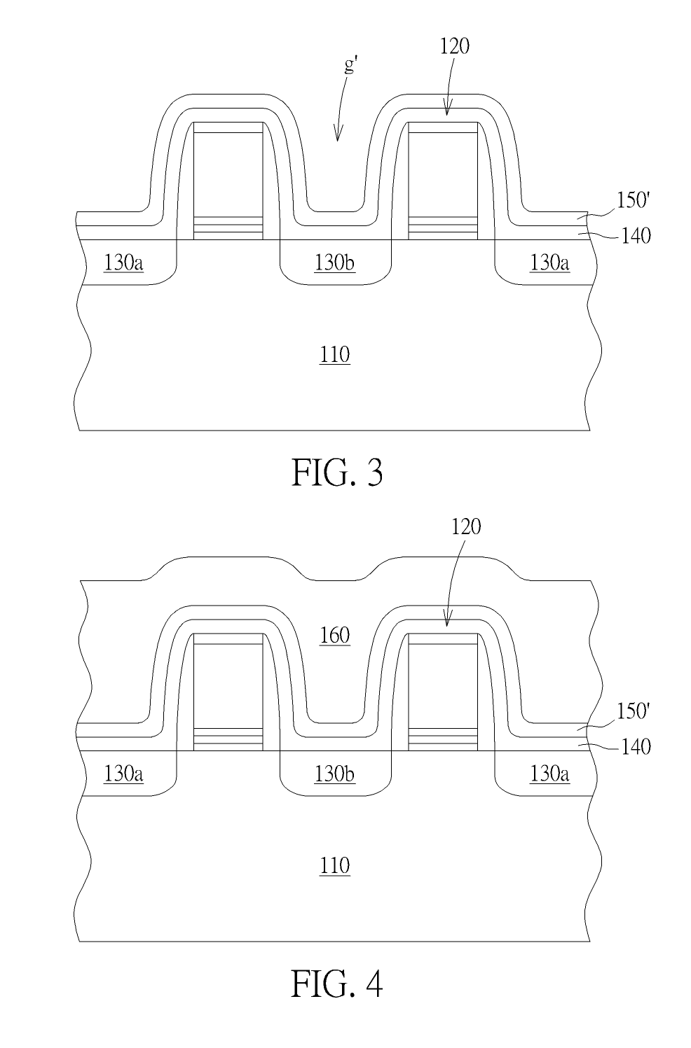

Thus, the first oxide layer 150 is ex-situ etched to etching the overhang parts 150a for forming the first oxide layer 150′, as shown in FIG. 3. Preferably, the overhang parts 150a are removed completely, and thus the opening of the gap g′ can be large enough for materials filling into without exposing the contact etch stop layer 130 or the gate structures 120 caused by over-etching the first oxide layer 150. In this embodiment, the first oxide layer 150 is ex-situ etched by a high density plasma (HDP) etching process, but it is not limited thereto. Due to the high density plasma (HDP) etching process being a directional bias etching process, the overhang parts 150a can be completely removed easily by controlling the high density plasma (HDP) etching process etching only vertically and not horizontally. It is emphasized that, just a part of the first oxide layer 150 is etched for modifying the first oxide layer 150 to have a desired profile without removing the entire first oxide layer 150.

A second oxide layer 160 is in-situ formed on the first oxide layer 150′ and fills the gap g′ between the two gate structures 120, as shown in FIG. 4. It is emphasized that, the step of etching the first oxide layer 150 (as shown in FIG. 3) and the step of forming the second oxide layer 160 are in-situ (as shown in FIG. 4) to simplify processes and improve device quality because these layers will not be polluted while transferring. Thus, the step of etching the first oxide layer 150 (as shown in FIG. 3) and the step of forming the second oxide layer 160 (as shown in FIG. 4) are preferably formed in a same chamber, but it is not limited thereto. In this embodiment, the second oxide layer 160 is in-situ formed by a high density plasma (HDP) depositing process to be paired with the high density plasma (HDP) etching process, so that the step of etching the first oxide layer 150 (as shown in FIG. 3) and the step of forming the second oxide layer 160 (as shown in FIG. 4) can be performed by the same high density plasma (HDP) device.

It is emphasized that, due to the second oxide layer 160 being formed by a high density plasma (HDP) depositing process while the first oxide layer 150 is formed by a sub-atmospheric chemical vapor deposition process, the hardness of the second oxide layer 160 is higher than the hardness of the first oxide layer 150, therefore improving the abrasion resistance while planarizing such as polishing in later processes.

Furthermore, the step of etching the first oxide layer 150 and then forming the second oxide layer 160 can be performed repeatedly until a desired oxide layer including the first oxide layer 150′ and the second oxide layer 160 are completely formed. Besides, the gap g′ being fully filled can be ensured by performing the step of etching the first oxide layer 150 and then forming the second oxide layer 160 repeatedly. More precisely, the step of etching the first oxide layer 150 after forming the second oxide layer 160 will also etch the second oxide layer 160. In other words, the second oxide layer 160 and the first oxide layer 150 will both be modified by etching after the second oxide layer 160 is formed.

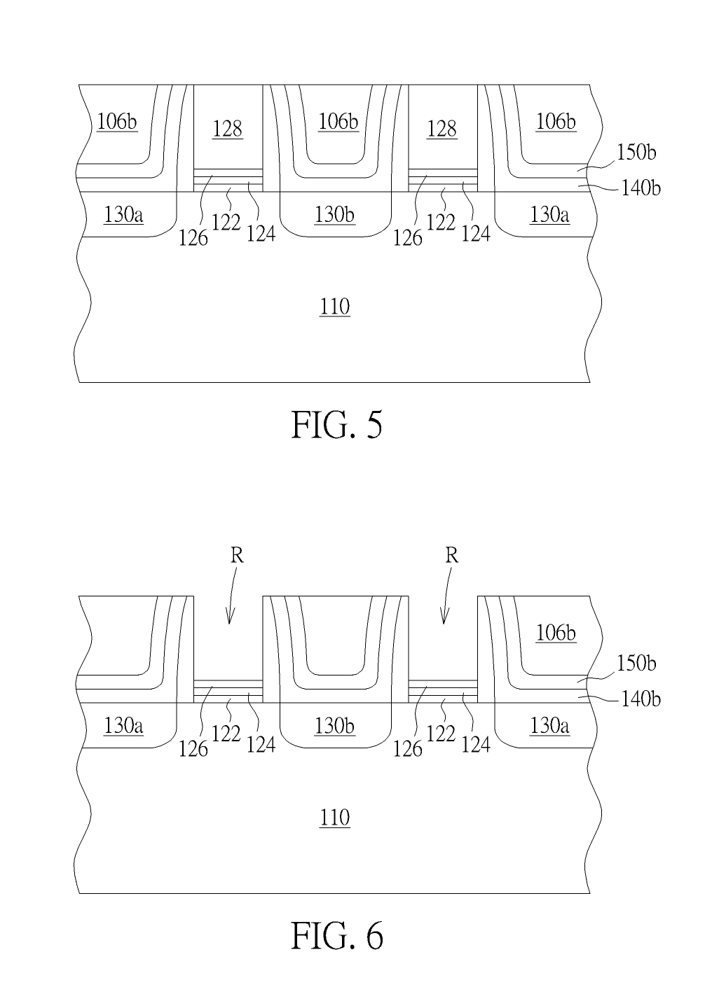

Then, the second oxide layer 160, the first oxide layer 150′, the contact etch stop layer 140 and the gate structures 120 are planarized until the gate structures 120 are exposed. In this embodiment, the second oxide layer 160, the first oxide layer 150′, the contact etch stop layer 140 and the gate structures 120 are planarized until the gates 128 of the gate structures 120 are exposed for replacing the gates 128 with two metal gates in later processes, thereby a planarized contact etch stop layer 140b, a planarized first oxide layer 150b and a planarized second oxide layer 160b are formed as shown in FIG. 5.

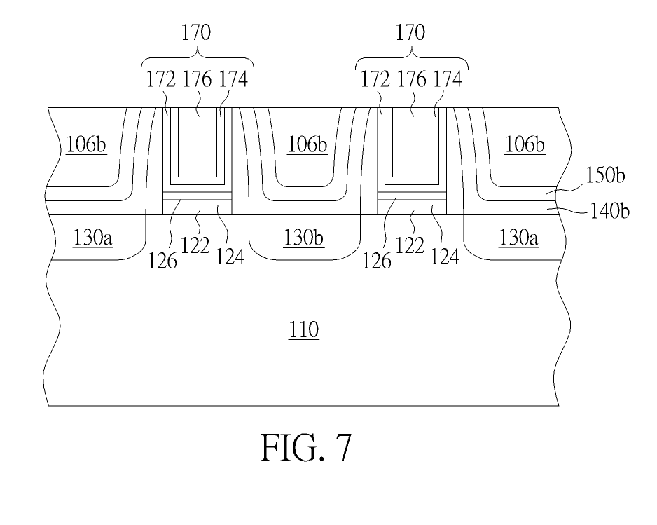

Please refer to FIGS. 6-7, the gates 128 are replaced by two metal gates 170 respectively. More precisely, the gates 128 are removed and thus recesses R are formed as shown in FIG. 6. Since a gate last for high-k first process is applied in this embodiment, only the gates 128 are removed and the barrier layers 126 remain for preventing the dielectric layers 124 from being polluted, but it is not limited thereto. In another embodiment, as a gate last for high-k last process is applied, the gates 128 and the dielectric layers 124 are removed (the barrier layers 126 are not formed in this embodiment). As shown in FIG. 7, the metal gates 170 including work function metal layers 172, barrier layers 174 and low resistivity 176 are formed from bottom to top in the recesses R. The method for forming the metal gates 170 may include the following step. A work function metal layer (not shown), a barrier layer (not shown) and a low resistivity (not shown) are sequentially formed to entirely cover the planarized second oxide layer 160b and fill the recesses R; and then, the low resistivity, the barrier layer and the work function metal layer are planarized until the planarized second oxide layer 160b is exposed. This means the two metal gates 170 including the work function metal layers 172 having a U-shaped cross sectional profile, the barrier layers 174 having a U-shaped cross sectional profile and the low resistivity 176 having a flat top surface are formed. Thereafter, later processes such as metal interconnection processes formed thereon may be carried out.

The work function metal layer 172 may be a single layer or a multilayer structure, composed of titanium nitride (TiN), titanium carbide (TiC), tantalum nitride (TaN), tantalum carbide (TaC), tungsten carbide (WC), titanium aluminide (TiAl) or aluminum titanium nitride (TiAlN) or others. The barrier layer 174 maybe a single layer or a multilayer structure composed of tantalum nitride (TaN) or titanium nitride (TiN) or others. The low resistivity 176 may be composed of low resistivity materials such as aluminum, tungsten, titanium aluminum (TiAl) alloy, cobalt tungsten phosphide (CoWP) or others.

To summarize, the present invention provides a method of forming an inter-level dielectric layer, which forms a first oxide layer to conformally cover the two gate structures and the substrate, ex-situ etching the first oxide layer by a high density plasma (HDP) etching process and then in-situ forming a second oxide layer on the first oxide layer and filling a gap between the two gate structures by a high density plasma (HDP) depositing process.

Thus, the gap filling, especially for the gate filling between the two gate structures, and defects caused by particles generating by previous processes, can be improved since the first oxide layer is formed conformally and then partially etched to remove its overhang parts. The abrasion resistance for the second oxide layer can be improved since the second oxide layer is formed by a HDP depositing process, wherein an oxide layer formed by a HDP depositing process has the hardness higher than an oxide layer formed by other processes such as a sub-atmospheric chemical vapor deposition process (SACVD). Besides, as the first oxide layer is etched and the second oxide layer is formed in-situ, processes can be simplified and pollution can be reduced.

Moreover, the first oxide layer is preferably formed by a sub-atmospheric chemical vapor deposition process while the second oxide layer is formed by a high density plasma (HDP) depositing process. Preferably, the step of etching first oxide layer and performing the second oxide layer is in a same chamber and may be performed sequentially and repeatedly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming an inter-level dielectric layer, comprising:
forming two gate structures on a substrate;
forming a first oxide layer to conformally cover the two gate structures and the substrate;
ex-situ etching the first oxide layer by a high density plasma (HDP) etching process; and
in-situ forming a second oxide layer on the first oxide layer and filling a gap between the two gate structures by a high density plasma (HDP) depositing process.

2. The method of forming an inter-level dielectric layer according to claim 1, further comprising:
forming a contact etch stop layer on the two gate structures and the substrate before the first oxide layer is formed.

3. The method of forming an inter-level dielectric layer according to claim 1, wherein the first oxide layer is formed by a sub-atmospheric chemical vapor deposition process (SACVD) process.

4. The method of forming an inter-level dielectric layer according to claim 1, wherein the steps of etching the first oxide layer and forming the second oxide layer are performed in a same chamber.

5. The method of forming an inter-level dielectric layer according to claim 1, wherein the steps of etching the first oxide layer and forming the second oxide layer are performed sequentially and repeatedly.

6. The method of forming an inter-level dielectric layer according to claim 1, wherein the thickness of the first oxide layer is in a range of 200˜300 angstroms while the spacing of the two gate structures is in a range of 400˜500 angstroms.

7. The method of forming an inter-level dielectric layer according to claim 1, wherein the first oxide layer has an overhang part between the two gate structures while the first oxide layer is formed.

8. The method of forming an inter-level dielectric layer according to claim 1, wherein the step of ex-situ etching the first oxide layer comprises etching the overhang part completely.

9. The method of forming an inter-level dielectric layer according to claim 1, further comprising:
planarizing the second oxide layer and the first oxide layer until the two gate structures are exposed after the second oxide layer are in-situ formed.

10. The method of forming an inter-level dielectric layer according to claim 1, wherein each of the two gate structures comprises a gate on the substrate and a spacer on the substrate beside the gate.

11. The method of forming an inter-level dielectric layer according to claim 10, wherein the two gates are exposed while the two gate structures are exposed.

12. The method of forming an inter-level dielectric layer according to claim 11, further comprising:
replacing the two gates by two metal gates respectively after the two gates are exposed.

13. The method of forming an inter-level dielectric layer according to claim 1, wherein the hardness of the second oxide layer is higher than the hardness of the first oxide layer.

14. The method of forming an inter-level dielectric layer according to claim 1, wherein the step of ex-situ etching the first oxide layer is ex-situ etching a part of the first oxide layer.
